(19) United States
(12) Patent Application Publication
(10) Pub. No.: US 2011/0014778 A1
(43) Pub. Date: Jan. 20, 2011

(54) Boron-10 coating process for neutron detector integrated circuit with high aspect ratio trenches

(76) Inventors: C. Christopher Klepper, Radford, VA (US); Eric P. Carlson, Christiansburg, VA (US); Michael D. Keitz, Hiwassee, VA (US); Othon R. Monteiro, Houston, TX (US)

Correspondence Address: ROBERT J. LAUF, 998 W. OUTER DRIVE, OAK RIDGE, TN, 37830, US

(21) Appl. No.: 12/460,494

(22) Filed: Jul. 20, 2009

(51) Int. Cl. H01L 21/326; C23C 14/46

(52) U.S. Cl. 438/469; 204/192.11; 257/E21.327

(57) ABSTRACT

A coating process to infill high aspect-ratio vias and trenches in semiconductor substrates with dense boron for the production of neutron detectors and other devices uses a vacuum cathodic arc or other source of fully ionized boron plasma. Biasing of the substrate is used to impart energies to the plasma ions directing them toward the substrate, while repulsing the electrons. The full ionization produced by the source allows control of the energies of the boron ions by means of the bias voltage. The bias is alternated between coating deposition at low ion energies and sputtering of already coated material by energetic ions. Most of the sputtered material comes off the substrate top surface and between the trenches or vias and much of it is redeposited, thereby contributing to the infill. The process is suitable for carbon, boron or similar light elements, and is of particular interest for ¹⁰B, an element having exceptionally high thermal neutron cross-section.

### CROSS REFERENCE TO RELATED APPLICATION

This application claims the benefit of Provisional Application Ser. No. 61/191,568 entitled, “Boron-10 coating process for neutron detector integrated circuit with high aspect ratio trenches” filed by the present inventor on Sep. 10, 2008, the entire disclosure of which is incorporated herein by reference.

### STATEMENT REGARDING FEDERALLY SPONSORED RESEARCH

This invention was made with Government support under Contract No. 1R43-AR05126201 awarded by the U.S. DHS/DNDO (SBIR Program) to HY-Tech Research Corp. and the Government has certain rights in this invention.

### BACKGROUND OF THE INVENTION

1. Field of the Invention

The invention pertains to the field of neutron detectors and more particularly to methods for making neutron detecting integrated circuits.

2.Description of Related Art

With the increased perception of a nuclear terrorist threat, the development of highly efficient, yet portable, reliable, low-power, thermal neutron detectors has been receiving great attention. Most recent designs [1-3] that aim to optimize all these desired properties feature a semiconductor wafer with a matrix of neutron reactive material, such as ¹⁰B or ⁶Li, thus forming closely interlaced regions of the neutron reactive material with the semiconductor material. This maximizes the probability that the charged particles that emerge from the nuclear reaction in the reactive material readily reach the semiconductor material, in which they generate an electrical signal.

The aforementioned matrix is produced by etching holes or trenches in the semiconductor material. The preferred semiconductor material is silicon due to the low cost and the existing manufacturing infrastructure for silicon-based integrated circuits. The preferred neutron reactive material is ¹⁰B, which has a substantially higher neutron capture cross-section that ⁶Li.

The trenches to be filled with the neutron reactive material can be as narrow as 1 micron and can have aspect ratios (i.e., height-to-width ratios) of as much as 25. Therefore, a major manufacturing challenge is to get dense and uniform infill of the trenches in a way that is technically feasible, as well as economically viable. One materials-related issue that contributes to this challenge is the fact that boron is one of the most difficult materials to process. It is the hardest elemental material, other than diamond. It has a high melting point (over 1000° C.). It is difficult to evaporate, and it has a super-low sputtering coefficient.

Infill methods that have already been explored for boron, and with a certain degree of success, include: (a) Electron beam evaporation with some collimation [2,3], (b) Chemical Vapor Deposition (CVD) [2], and (c) Use of sub-micron boron particles, applied to the etched substrate by spin coating and driven into the trenches by applying mechanical vibration to the substrate [3].

Existing methods do, however, suffer from various shortcomings. For example, CVD methods require the use of costly and hazardous gaseous boron compounds. CVD methods typically require elevated temperatures, which can damage the etched features in the semiconductor substrate. Collimated electron beam evaporation deposits a boron coating on the ridges between the trenches that is as thick as the fill between the trenches. This adds cost to the process as the excess boron is difficult to remove and, also, because the ¹⁰B isotope is too expensive to waste. The sub-micron particle technique is limited due to the extreme difficulty in the production of sub-micron boron particles without the total loss of the particles to oxidation.

### Objects And Advantages

Objects of the present invention include the following: providing a method for depositing boron onto a silicon substrate; providing a method for depositing boron into surface trenches with a high fill factor; providing a low-temperature process for depositing boron onto silicon structures; providing a boron coating having low impurity levels; providing a boron coating having high electrical resistivity; and, providing a neutron detecting element having high density, high resistivity boron deposited between silicon structural features. These and other objects and advantages of the invention will become apparent from consideration of the following specification, read in conjunction with the drawings.

### SUMMARY OF THE INVENTION

According to one aspect of the invention, a method for fabricating a neutron detecting device comprises: fabricating a semiconductor wafer having raised surface features thereon; generating a stream of boron ions and directing the stream onto the semiconductor wafer at a selected impingement angle; and, applying a cyclic bias voltage to the semiconductor wafer, wherein the bias voltage varies between a first value conducive to deposition and a second value conducive to self-sputtering of the boron.

According to another aspect of the invention, method for depositing boron onto a substrate having raised surface features thereon comprises the following steps: generating a stream of boron ions and directing the stream onto the substrate at a selected impingement angle; and, applying a cyclic bias voltage to the substrate, wherein the bias voltage varies between a first value conducive to deposition and a second value conducive to self-sputtering of the boron.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting embodiments illustrated in the drawing figures, wherein like numerals (if they occur in more than one view) designate the same elements. The features in the drawings are not necessarily drawn to scale.

FIG. 1 is a schematic Illustration of a cathodic arc plasma source. The “blade-style” filter, with two current carrying baffles, is one of the various schemes used to remove particulate contamination from cathodic arcs and is preferred for the boron cathodic arc.

FIG. 2 is a schematic diagram of a two stage deposition process.

FIG. 3 is a schematic illustration of an efficient, solid-state neutron detector concept, for which the present invention is suitable.

FIG. 4 shows computed B self-sputtering yield as a function of the energy of the boron ions for normal and for a 50° (with respect to the substrate) incidence.

FIG. 5 shows computed Cu self-sputtering yield as a function of the energy of the copper ions (Cu⁺) for normal and for 50° incidence.

FIG. 6 is an FIB/SEM image in cross-section of carbon infill produced using the present invention.

FIG. 7 Illustrates one preferred pulse-shape for the optimal trench fill according to one embodiment of the invention.

FIG. 8 is an SEM image in cross section showing boron infill produced using the present invention.

### DETAILED DESCRIPTION OF THE INVENTION

The present invention provides an alternative method of boron infill with potential advantages in manufacturing economy. It is preferably based on the use of cathodic arc-based plasma deposition. Processes have been reported for depositing copper into trenches and vias to make conventional integrated circuits [see, for example, O. R. Monteiro, “Novel metallization technique for filling 100-nm-wide trenches and vias with very high aspect ratio,” Journal of Vacuum Science and Technology B 17, no. 3 (1999) 1094-1097] and Applicants postulated that a similar approach might be used to deposit boron into deeply-etched structures for neutron detector elements.

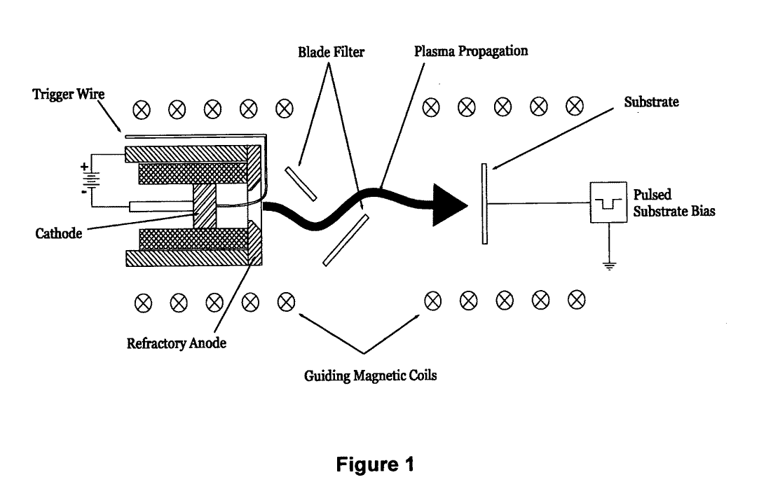

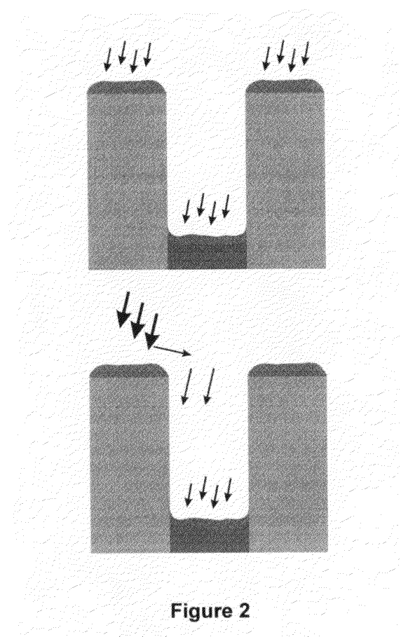

Cathodic arc discharges can operate in vacuum (no background gas required), with all the ionized material coming from the cathode as shown in FIG. 1. This allows for pure material deposition, because the purity of the material can be controlled. In the case of boron, the additional advantage is the absence of boron-based gases, which are costly both to make and to handle, because of safety and health concerns. The development of a cathodic arc plasma source using a heated boron cathode as the consumable material has been documented in a patent as well as in the scientific literature [6-9].

The inventive technique makes use of the fully ionized nature of the plasma emanating from the cathodic arc to tailor the ion energies such that they create the desired infill of the trenches etched in the silicon wafer, as well as minimize the coating of the top surfaces. This is accomplished by varying the electrical bias that is applied to the substrate (the silicon wafer in this case) such that in part of the cycle, the boron ions are attracted to the wafer with low energies to promote deposition (i.e, film formation) and, in the other part of the cycle, high negative voltage is applied to generate energetic ions at the substrate, to promote sputtering of the boron layer already deposited (self-sputtering). The concept is that coating material is mostly removed from the regions between trenches during this second phase of the substrate bias cycle and that much of this material gets redeposited in the trenches during the deposition cycle that follows. Material sputtered inside the narrow trenches cannot easily come out of the trenches and is redeposited inside the trench.

In the original application of this general technique, Monteiro used a pulsed cathodic arc source with a copper cathode. During each single pulse of the arc source, the substrate bias was pulsed multiple times in the manner just described. In Monteiro's experiments, the optimal infill solution was found when the duty cycle of the substrate bias program was about 50%. That is, when the duration of the sputtering phase equaled that of the deposition phase. The optimal bias voltages where approximately—100V for the sputtering phase and approximately 0V for the deposition phase.

Although the present invention is conceptually similar to Monteiro's technique, as developed for the deposition of transition metals on patterned silicon, it greatly departs from this background technique in that it is applied to elements that are much lighter (having much lower atomic mass) than transition metals. As will be described in more detail, light elements, such as carbon, C, and boron, B, have substantially lower self-sputtering coefficients than do the metals, and thus it was not clear if the technique could be extended to these light elements or what modifications to the process would be needed.

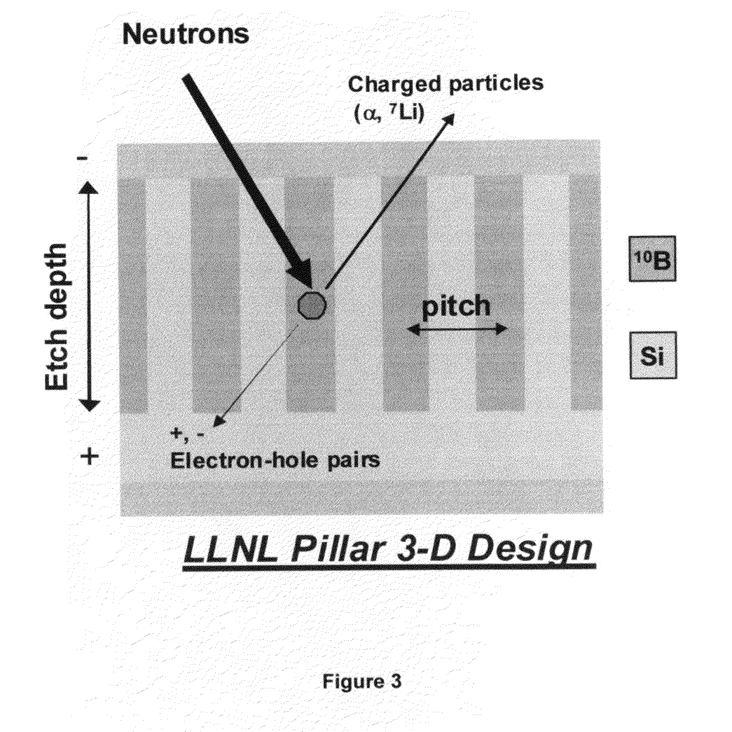

The initial proof-of-principle of the present invention was carried out in connection with an efficient thermal neutron device under development by the Lawrence Livermore National Laboratory (LLNL), which also features high enough aspect ratio trenches to benefit from this invention. LLNL's device design, referred to as the Pillar Array detector, is shown in FIG. 3. The design is a technology advance that can increase the neutron detection efficiency from the current (mostly planar) solid-state devices 2-5% [10, 11] towards 70% or higher. The platform consists of etched pillar arrays of PIN diodes, which are grown on a planar semiconductor substrate. The converter material and the detector material are inter-digitated such that charged particles from the thermal neutron ¹⁰B reaction have a significantly higher probability of impinging the detector material due to the close proximity.

Boron 10 (¹⁰B) is the most common converter material due to its excellent thermal neutron cross-section. The thermal neutron reaction is

¹⁰B+n→α(1.47 MeV)+⁷Li(0.84 MeV).

The resulting charged particles subsequently enter the semiconductor detector to create electrons and holes for generation of the electrical signal. These particles can travel inside the converter material only for a short distance (˜3 μm). The LLNL “Pillar Array Detector” design is a result of optimization studies that have achieved maximum efficiency in the utilization of the charged particles by (a) minimizing the converter material that these particles will have to traverse, on the average, while (b) maximizing the probability of the neutrons striking converter material and of charged particles encountering semiconductor material. In this Pillar Detector, it is possible to separate the constraints on the boron thickness via defining the pillar height (etch depth), which defines the material that will absorb the neutron flux. At the same time it is possible to define the pitch of the pillar arrays to have the highest possible interaction of the alphas with the semiconductor pillar to insure charged carrier generation in the pillars as shown generally in FIG. 3.

As indicated, boron is used to convert neutrons to alpha particles. The method for deposition of boron during the device fabrication stage must have (A) high fill-factor to minimize air gap for high alpha generation efficiency; (B) low deposition process temperature to minimize reaction between the film and the semiconductor substrate; (C) low impurity content to minimize scattering of the alpha particles; (D) high resistivity to minimize leakage current between the semiconductor pillar structures. These criteria are necessary for obtaining the desired high neutron detection efficiency with the solid-state neutron detectors that have the above-described architecture.

The cathodic arc process used herein is that generally taught by Klepper et al. in U.S. Pat. No. 6,495,002, the entire disclosure of which is incorporated herein by reference. The cathodic arc deposition technique has the potential of meeting all these criteria, because (1) Cathodic arc deposition is known to deposit dense, amorphous coatings, (2) As a plasma based coating technology it does not require the elevated temperatures, such as needed in CVD; the ions provide the energy needed to get the deposited adatoms “packed” into a dense layer, (3) The ability to run a cathodic arc discharge on a pure boron cathode, by heating the cathode to provide the conductivity [6]and in the absence of any background gas, allows for pure coatings, and (4) The very same reasons also provide for the desired high resistivity of the deposited material, when operated at room temperature. In other words, at room temperature, amorphous boron is a great insulator and the absence of any metal impurities and/or carbon from either from the cathode or the ambient background assures that this property is preserved in the inter-pillar coating.

Most of the process development and proof-of-principle studies were carried out with a carbon (POCO Graphite, AXF-5Q) cathode. As in the case of a metal cathode, a carbon cathode does not need to be heated. It is sufficiently conductive to work as such at room temperature. Unlike a metal cathode, a carbon cathode behaves much more like a sintered boron cathode in a number of ways, including the nature of the macroparticles it generates. A metal cathode produces mostly molten droplets, whereas carbon and boron macroparticles are mostly in the form of solid particles. Boron ions are primarily singly ionized, while carbon ions are exclusively produced in the singly ionized state. Most importantly, carbon (amu˜12) has a similarly low atomic mass as boron (amu˜10.8 for natural boron, amu=10 for ¹⁰B).

The absence of cathode heating, the lower cost of cathode material and the overall simpler nature of the carbon cathodic arc allowed for more streamlined process development than would have been possible using the boron cathodic arc. Nevertheless, one of the near optimal recipes was also repeated with the boron cathodic arc.

Furthermore, computational modeling using static and dynamic versions of the ion-surface interaction code TRIM was used to establish that the experimental results for carbon are also valid for boron and that any proof-of-principle based on carbon studies would also apply to boron. The same modeling was also used to show that sputtering yields and their dependence on both incident energy of the ions and the angle of their incidence, for both carbon and boron, are substantially different from the higher atomic mass transition metals, for which this technique was originally conceived.

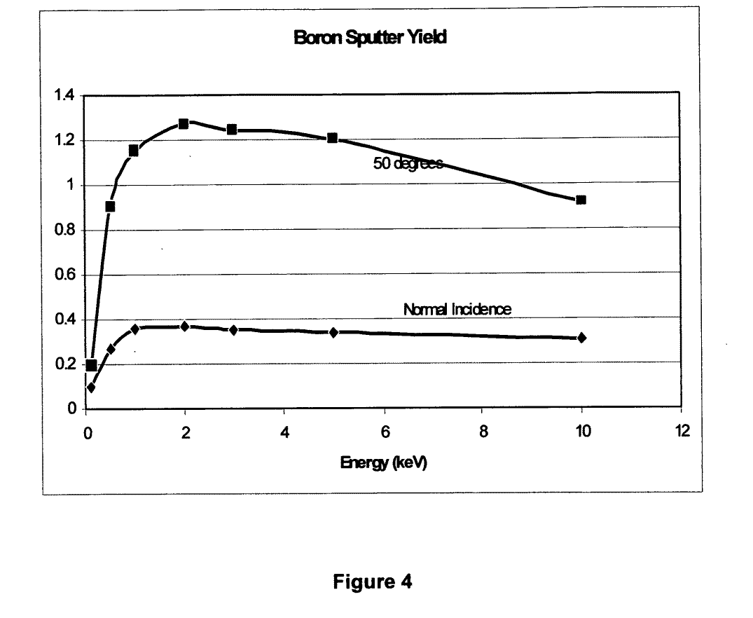

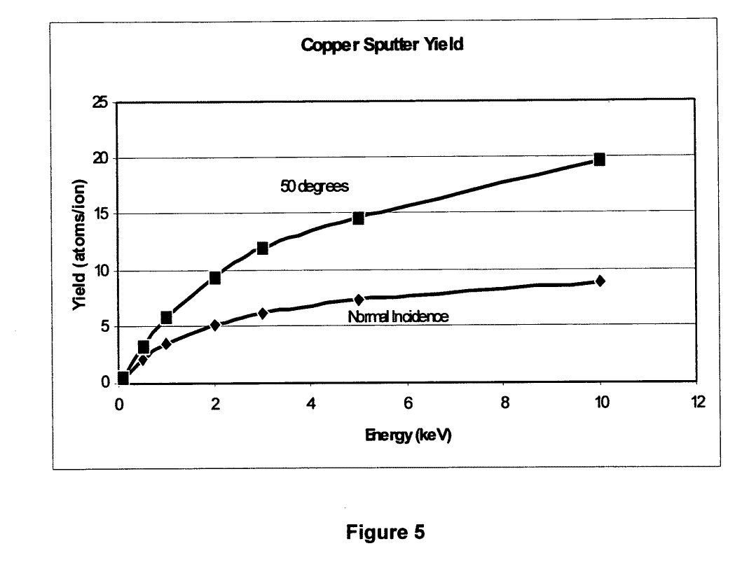

FIG. 4 is an example of such modeling output. Shown here is the sputtering yield for boron on boron (“self-sputtering”) as a function of incident energy for normal incidence and 50° C. One key thing to notice is the strong dependence of the self-sputtering on angle of incidence of the boron ions onto the already deposited boron. The result for carbon is identical. For comparison, the same information is plotted in FIG. 5 for copper.

When comparing the results of FIG. 5 to those of FIG. 4, it becomes clear why drastically different process conditions are required for the light elements, and why the process claimed herein constitutes a significant improvement upon the existing art.

### EXAMPLE

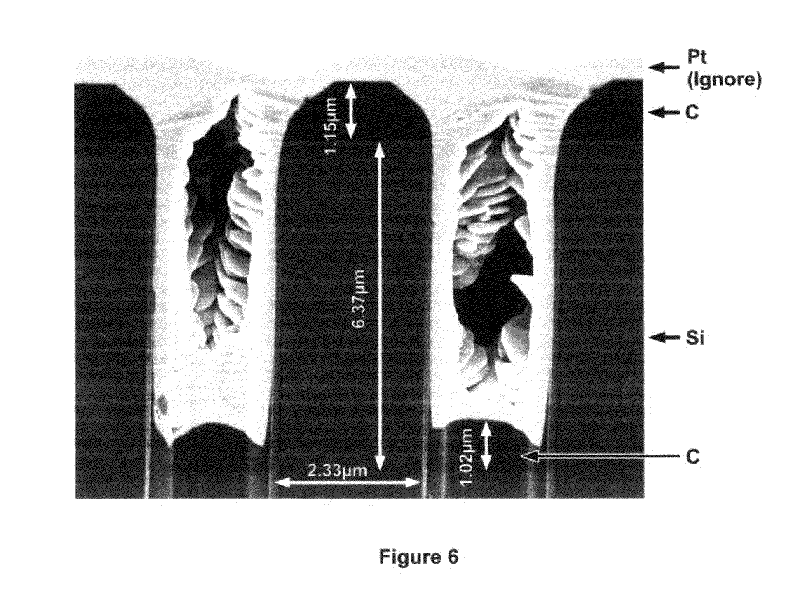

FIG. 6 shows an image from Focused Ion Beam/Scanning Electron Microscopy (FIB/SEM) analysis of carbon infill produced with only 80×1 s cathodic arc pulses. A minimum of 60 s between arc pulses was maintained. This, together with keeping the arc pulses down to 1 s, were intended to prevent any overheating of the substrate (by the ions) which could lead to graphitic crystal growth. The white (snow-like) material in the image is the sacrificial Pt coating used in the FIB technique and should therefore be ignored.

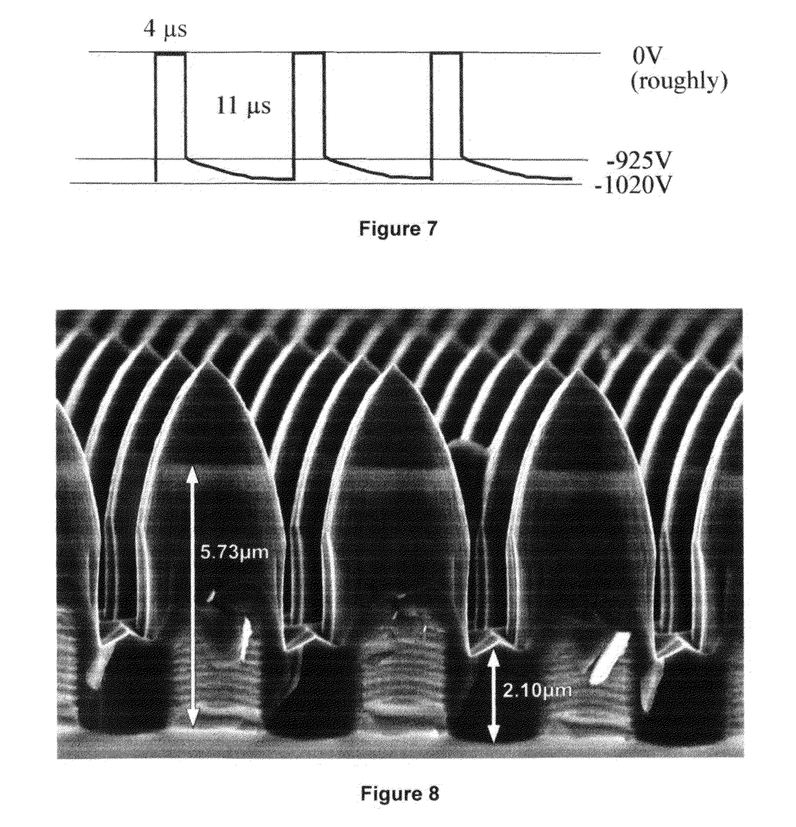

The “pulsed-dc” electrical bias applied to the substrate alternated between sputtering and deposition phases at a rate of 66 kHz with an 11 μs dwell at an average of about −970V (sputter phase) and a 4 μs dwell at about 0V (deposition phase). FIG. 7 illustrates the actual pulse shape delivered by the bias power supplies. Existing power supplies were used in this process development. They consisted of a MDX-5k (5 kW driver) and a Spark-LE-V spark-suppressor that was used here as a reasonably flexible pulser, thanks to the “−V” variable frequency option, (both of these components are made by Advanced Energy Industries, Inc., 1625 Sharp Point Drive, Fort Collins, Colo. 80525). However, as versatile as the system proved to be, it could not deliver 50% duty cycle, which was the optimal duty cycle found by the Monteiro et al. in their Cu infill studies, as well as the optimal predicted for the light elements (B, C) application. Thus, the bias recipe shown in FIG. 7 is the optimal possible with this particular hardware. Further optimization is very likely with more versatile power supplies, which could go to 50% duty cycle without requiring a reduction in the voltage, as is the case with the present system.

### EXAMPLE

In another experiment, carbon infill was produced with 250×1 s arc pulses and pulsed-dc bias at 66 kHz with 11 μs /4 μs at about −970V / 0V. This means the same conditions as in the previous example, but with more than triple the deposition time. As in the previous example, a minimum of 60 s between arc pulses was maintained and the system was operated with a C cathode. Since shapes of the pillar-etched samples used for these studies varied somewhat from batch-to-batch, the substrates are obviously not identical. However, for the purposes of a proof-of-principle, these findings make a very good case of the feasibility of this cathodic arc-based technique for filling high-aspect ratio trenches with light elements, such as B and C.

It is important to note that no damage to the substrate was seen in any coated samples studied by FIB/SEM, i.e., the Si substrate is not in any way damaged by the energetic ion coating process of the cathodic arc. There is no evidence of any fracture initiation in the Si or of any significant sputtering of the Si by the carbon ions. This is very important, because the competing CVD process is known to lead to occasional damage to the pillars as a result of the very high temperatures that the process requires.

The process tends to create cone-shaped structures on the pillar tops, visible in FIG. 6. This is attributed to the strong angular dependence in the self-sputtering in light elements and it is the mechanism that self-limits the growth of the coating on the tops of the pillars. Technology to remove limited amount of excess B on pillar tops, based on etching with hydrogen ions, already exists. The important thing is to keep this coating limited, so that the top-coating removal step is also a limited part of the overall manufacturing process. When the deposition is planned correctly, the cones are formed only in the coating and they limit the coating on the pillar-tops as desired. Improper programming of the bias voltages could lead to some sputtering of the Si, which would lead to some Si content added to the ¹⁰B, thus potentially reducing the efficiency of the detector.

### EXAMPLE

FIG. 8 is an SEM image in cross-sectional sectional view, of a boron coated sample using a preferred recipe, as developed for C as described in the preceding Examples, and applying it to B for ˜183 s of deposition time (about 90 arc discharges). Two immediate observations from this image are (a) the occurrence of the same peaked, conical pillar-top coating structures as were seen with carbon and indicate self-limited growth on pillar tops, and (b) the cleanliness of the boron deposition, i.e., the absence of the large presence of the sub-micron to micron-size “macroparticles” that littered the carbon coatings. The latter is a result of the more refined macroparticle filter in the larger coating facility used in the boron experiments. (Filter baffles are shown schematically in FIG. 1.)

Closer observation of FIG. 8 reveals substantial and fully dense coating that fills the bottom of the inter-pillar spaces. Even closer observation would reveal a fair amount of “wall coating” in the form of a widening of the pillar structures in the bottom ¾ of the structures. Further analysis, e.g. using the Focused Ion Beam (FIB) approach, revealed the wall coating more clearly. Another observation is the excellent uniformity of the process from the uniformity of the pillar-top coating features seen in the background.

It will be appreciated that the pulse shape of the bias voltage (e.g., as shown in FIG. 7) may be varied significantly, depending on the specific device geometry and process objectives. For example, a pulse rate of 66 kHz was selected with the goal of minimizing the likelihood of arc discharges, which could damage the workpiece. However, further tests conducted at pulse rates as low as 10 kHz showed no evidence of damage attributable to arc discharge on the surface of the workpiece. In one test conducted at about 10 kHz, the bias voltage was alternated on a 50% duty cycle (i.e., half the cycle at about 0 V and half the cycle at about −900 V).

It will be further appreciated that the duty cycle of the ion source may also be varied. In the exemplary embodiments the ion source was on for 1-2 s and off for 15-60 s, a duty cycle that avoided undue heating of the workpiece. In these tests, the workpiece was not actively cooled. Thus, the skilled artisan may easily add a cooling system to the substrate holder if a more intense duty cycle is desired. Various suitable approaches for actively cooling the workpiece are well known in the art.

In the foregoing examples, the semiconductor wafer was positioned such that the stream of boron ions (shown at the right side of FIG. 1) was impinging approximately normal to the surface of the wafer. In some cases, for particular applications, it might be desired to position the wafer at some other angle, or rotate the wafer. It will be understood that when a high bias voltage is applied to the wafer, electrostatic forces will perturb the trajectories of the ions and generally direct them into more or less normal impingement upon the plane of the wafer.

Specific process conditions have been shown for some preferred embodiments of the invention. It will be appreciated that the preferred process variables may vary depending on factors such as the depth and aspect ratio of the surface features, composition of the substrate, etc. In the general case, Applicants prefer to hold the bias at values of at most about −110V and more preferably close to 0V during the deposition phase and at least −800V and more preferably at least −900V during the sputtering phase.

In the exemplary embodiments, the preferred source of boron was a cathodic arc-based plasma source. It will be appreciated, however, that any source capable of producing sufficiently ionized boron vapor may be used with this invention. Although Applicants prefer to use a source that will produce boron vapor at near full ionization, such as the heated boron cathode source used in the examples, it is conceivable that one could induce more ionization in the vapor from magnetron sputtering source by the addition of radio-frequency or microwave power to the downstream region of the source and near the substrate. Another potentially suitable approach is the application of an emerging technology called High Power Impulse Magnetron Sputtering (HIPIMS, also known as High Impact Power Magnetron Sputtering and High Power Pulsed Magnetron Sputtering, HPPMS), which is a method for physical vapor deposition of thin films also based on magnetron sputter deposition. However, HIPIMS uses extremely high power densities of the order of kW/cm² in short pulses (impulses) of tens of microseconds at low duty cycle (on/off time ratio) of <10%, and is known to lead to substantial ionization of the sputtered metal vapor. Although it is known that sputtering of boron is highly inefficient, it is possible that HIPIMS applied to boron could potentially ameliorate this problem and be competitive with the cathodic arc approach as a result of the anticipated absence of microparticulate contamination in the case of HIPIMS. It is noted, however, than any ionization fraction that is substantially lower than 100% (i.e. the theoretical ionization in cathodic arc) could lead to less infill efficiency due to the larger deposition during the sputtering cycles, or require a significant departure from the optimal recipes described herein.

In the exemplary embodiments, the preferred neutron detector architecture was that of LLNL's Pillar Array Detector. This was because it features the most challenging aspect ratios and this provides the present, novel coating technique the most advantage over the competing approaches. However, any other solid-state, neutron detector architecture using ¹⁰B as the neutron active material will require a process for the deposition of the ¹⁰B onto the substrate and inside any features that are characteristic of its architecture. An example that closely resembles that of LLNL's architecture is the aforementioned detector described by McGregor et al. in U.S. Pat. No. 7,164,138.

A fuller understanding of the invention may be obtained by consulting background material in the following references, the entire disclosures of which are incorporated herein by reference.
1. Nikolic et al., “Semiconductor Materials Matrix for Neutron Detection,” Patent Application, Pub. No. US2006/0255282 A1, Pub. Date: Nov. 16, 2006.
2. R. J. Nikolic, C. L. Cheung, C. E. Reinhardt, T. F. Wang, “Roadmap for High Efficiency Solid-State Neutron Detectors,” UCRL-PROC-213583, Lawrence Livermore National Laboratory, July 2005.
3. McGregor et al, “High-Efficiency Neutron Detectors and Methods of Making Same,” U.S. Pat. No. 7,164,138, Jan. 16, 2007.
4. O. R. Monteiro, “Novel metallization technique for filling 100-nm-wide trenches and vias with very high aspect ratio,” Journal of Vacuum Science and Technology B 17, no. 3 (1999) 1094-1097.
5. D. Sanders, A. Anders, “Review of cathodic arc deposition technology at the start of the new millennium,” Surface & Coatings Technology 133-134 (2000) 78-90.
6. M. S. Morrow, D. E. Schechter, C. C. Tsai, C. C. Klepper, R. C. Hazelton, and J. Niemel “Microwave processing of pressed boron powders for use as cathodes in vacuum arc sources,” U.S. Pat. No. 6,562,418, May 13, 2003.
7. C. C. Klepper, J. M. Williams, R. C. Hazelton, E. J. Yadlowsky, et al., “Amorphous Boron Coatings Produced via Vacuum Arc Deposition Technology,” Journal of Vacuum Science & Technology A: Vacuum, Surfaces, and Films, 20, Issue 3 (May 2002) pp. 725-732.
8. J. M. Williams, C. C. Klepper, R. C. Hazelton, and M. D. Ketitz, J. E. Lemons, M. Anabtawi, S. Luque, G. M. Ludtka, L. Riester, J. Qu, J. J. Truhan, Jr. “Boron and Boron based Coatings as Deposited by the Cathodic Arc Technique,” Surface Modification Technologies, T. S. Sudarshan and J. J. Stiglich, Eds., ASM International®, Materials Park, Ohio, USA (copyright ©2006) p. 72.
9.J. M. Williams, C. C. Klepper, D. J. Chivers, R. C. Hazelton, J. J. Moschella and M. D. Keitz, “Boron Ion Implantation into Silicon by Use of the Boron Vacuum-Arc Plasma Generator,” CP866, Ion Implantation Technology, K. J. Kirkby, R. Gwilliam, A. Smith, and D. Chivers, Eds., American Institute of Physics (2006) p. 261.
10. M. Wielunski, R. Schutz, E. Fantuzzi, A. Pagnamenta, W. Wahl, J. Palfálvi, P. Zombori, A. Andrasi, H. Stadtmann and C. H. Schmitzer, “Study of the sensitivity of neutron sensors consisting of a converter plus Si charged-particle detector,” Nuclear Instruments and Methods in Physics Research A 517 (2004) 240-253.
11. H. K. Gerscha, D. S. McGregor and P. A. Simpson, “The effect of incremental gamma-ray doses and incremental neutron fluences upon the performance of self-biased ¹⁰B-coated high-purity epitaxial GaAs thermal neutron detectors,” Nuclear Instruments and Methods in Physics Research A 489 (2002) 85-98.
12. R. J. Nikolic, A. M. Conway, C. E. Reinhardt, R. T. Graff, T. F. Wang, N. Deo, and C. L. Cheung, “6:1 aspect ratio silicon pillar based thermal neutron detector filled with 10B,” Appl. Phys. Lett., 93, 133502 (2008).

We claim:

1. A method for fabricating a neutron detecting device comprising:
fabricating a semiconductor wafer having raised surface features thereon;
generating a stream of boron ions and directing said stream onto said semiconductor wafer at a selected impingement angle; and,
applying a pulsed DC bias voltage to said semiconductor wafer, wherein said bias voltage alternates between a first value conducive to deposition and a second value conducive to self-sputtering of said boron.

2. The method of claim 1 wherein said impingement angle is substantially normal to the plane of said semiconductor wafer.

3. The method of claim 1 wherein said boron ions are generated in a process selected from the following group: cathodic arc; magnetron sputtering; and high power impulse magnetron sputtering.

4. The method of claim 1 wherein said first value of said bias voltage, conducive to deposition, is between about −100 V and about 0 V.

5. The method of claim 1 wherein said second value of said bias voltage, conducive to self sputtering, is at least −800 V.

6. The method of claim 1 wherein said pulsed DC bias voltage cycles between said first and second values at a repetition rate of at least 10 KHz.

7. The method of claim 6 wherein one cycle of said pulsed DC bias voltage comprises alternately holding said first value for about 25 to 50% of said cycle and holding said second value for 75 to 50% of said cycle.

8. The method of claim 1 wherein said boron ions comprise predominantly ¹⁰B.

9. The method of claim 1 wherein said semiconductor wafer is actively cooled.

10. A method for depositing boron onto a substrate having raised surface features thereon comprising the following steps:
generating a stream of boron ions and directing said stream onto said substrate at a selected impingement angle; and,
applying a pulsed DC bias voltage to said substrate, wherein said bias voltage alternates between a first value conducive to deposition and a second value conducive to self-sputtering of said boron.

11. The method of claim 10 wherein said impingement angle is substantially normal to the plane of said substrate.

12. The method of claim 10 wherein said boron ions are generated in a process selected from the following group: cathodic arc; magnetron sputtering; and high power impulse magnetron sputtering.

13. The method of claim 10 wherein said first value of said bias voltage, conducive to deposition, is between about −100 V and about 0 V.

14. The method of claim 10 wherein said second value of said bias voltage is at least −800 V.

15. The method of claim 10 wherein said pulsed DC bias voltage cycles between said first and second values at a repetition rate of at least 10 KHz.

16. The method of claim 15 wherein one cycle of said pulsed DC bias voltage comprises alternately holding said first value for about 25 to 50% of said cycle and holding said second value for 75 to 50% of said cycle.

17. The method of claim 10 wherein said boron ions comprise predominantly ¹⁰B.

18. The method of claim 10 wherein said substrate is actively cooled.
